(19) United States
(12) Patent Application Publication
(10) Pub. No.: US 2025/0355034 A1
(43) Pub. Date: Nov. 20, 2025

(54) MONITORING AN ELECTRIC POWER GRID

(71) Applicant: Reactive Technologies Limited, Oxford (GB)

(72) Inventors: Duncan BURT, Oxford (GB); Roya AHMADIAHANGAR, Oxford (GB); Poria ASTERO, Oxford (GB); Daniel GHEORGHE, Oxford (GB)

(21) Appl. No.: 19/285,572

(22) Filed: Jul. 30, 2025

Related U.S. Application Data
(63) Continuation of application No. PCT/EP2024/052531, filed on Feb. 1, 2024.

(30) Foreign Application Priority Data
Feb. 3, 2023 (GB) 2301547.2

(51) Int. Cl. G01R 31/08

(52) U.S. Cl. CPC G01R 31/086

(57) ABSTRACT

This document discloses a solution for a method of monitoring an electric power grid. According to an aspect, a method comprises: detecting a fluctuation on the power grid, obtaining, while the fluctuation is effective, measurements of one or more electrical parameters in the electric power grid at a given number of grid measurement points, determining, at least in part based on the one or more electrical parameters and the properties of the fluctuation, the relationship of the measured parameters at the given number of grid measurement points and determining, based on the relationship, relative voltage sensitivity those measurement points have relative to the detected fluctuation.

### CROSS-REFERENCE TO RELATED APPLICATIONS

This application is a continuation under 35 U.S.C. § 120 of International Application No. PCT/EP2024/052531, filed Feb. 1, 2024, which claims priority to GB Application No. GB2301547.2, filed Feb. 3, 2023, under 35 U.S.C. § 119 (a). Each of the above-referenced patent applications is incorporated by reference in its entirety.

### TECHNICAL FIELD

The invention relates to measurement-based monitoring of an electric power grid and, for example, to determining relative voltage sensitivity of the electric power grid.

### TECHNICAL BACKGROUND

Since the standardisation of the frequency of alternating current (AC) electricity in large scale electric power grids in the mid-20th century around the globe, consumers of electricity have been able to enjoy a consistent and dependable service of electricity, ensuring safe and reproducible use of electrical appliances. Provision of such a reliable service may include monitoring the characteristics of an electric power grid and taking measures to anomalies detected in the grid.

For example, system strength, or the ability of the system to resist voltage changes at any given location, is a parameter which has been monitored in electric power grids. Inverter-Based generation resources do not participate effectively in voltage control and System Strength to support the operation of power grids, therefore as the level of these sources rises, in the future, the system strength in electric power grids will get lower and will need to be monitored to ensure minimum levels of inertia and system strength to maintain resilient and reliable grid operation.

Thus, reliable measurement of relative voltage sensitivity or system strength is important in electric power grids.

### BRIEF DESCRIPTION

The invention is defined by the independent claims. Embodiments are defined in the dependent claims.

According to an aspect, there is provided a method for monitoring an electric power grid, the method comprising: detecting a fluctuation on the power grid; obtaining, while the fluctuation is effective, measurements of one or more electrical parameters in the electric power grid at a given number of grid measurement points; determining, at least in part based on the one or more electrical parameters and the properties of the fluctuation, the relationship of the measured parameters at the given number of grid measurement points; and determining, based on the relationship, relative voltage sensitivity those measurement points have relative to the detected fluctuation.

In an embodiment, the fluctuation is at least one of an intentionally caused voltage modulation or a fluctuation on the power grid caused by for example, switching, load change, or transformer tapping, i.e. forced, ambient or transient oscillations in the electric power grid. In an embodiment, the relationship is correlation.

In an embodiment, the measurements of one or more electrical parameters comprise measuring voltage waveform amplitudes, derivatives, transients and shapes.

In an embodiment, the method further comprises analysis by, for example, using machine learning to establish the relationship between different two or more measurement points of the electric power grid by using, as training data, a first set of measurement data obtained at the first measurement point and a second set of measurement data obtained at the second measurement point.

According to another aspect, there is provided a system for monitoring an electric power grid, the system comprising means for performing: detecting a fluctuation on the power grid; obtaining, while the fluctuation is effective, measurements of one or more electrical parameters in the electric power grid at a given number of grid measurement points; determining, at least in part based on the one or more electrical parameters and the properties of the fluctuation, the relationship of the measured parameters at the given number of grid measurement points; and determining, based on the relationship, relative voltage sensitivity those measurement points have relative to the detected fluctuation.

According to another aspect, there is provided a computer program product readable by a computer and comprising computer program instructions that, when executed by the computer cause execution of a computer process comprising: detecting a fluctuation on the power grid; obtaining, while the fluctuation is effective, measurements of one or more electrical parameters in the electric power grid at a given number of grid measurement points; determining, at least in part based on the one or more electrical parameters and the properties of the voltage modulation signal, the relationship of the measured parameters at the given number of grid measurement points; and determining, based on the relationship, relative voltage sensitivity those measurement points have relative to the detected fluctuation.

### BRIEF DESCRIPTION OF THE DRAWINGS

In the following the invention will be described in greater detail by means of preferred embodiments with reference to the accompanying drawings, in which

FIG. 1 illustrates an example of an electric power grid to which embodiments of the invention may be applied;

FIG. 2 is a flow diagram illustrating an embodiment;

FIG. 3 is a signalling diagram illustrating an embodiment;

FIG. 4 illustrates a simple example of a part of an electric grid;

FIG. 5 is a flow diagram illustrating an embodiment;

FIG. 6 illustrates a simplified structure of the electric power grid;

FIG. 7 illustrates an example of the operation of a measuring system of an embodiment; and

FIG. 8 illustrates a block diagram of an apparatus according to an embodiment of the invention.

### DETAILED DESCRIPTION OF EMBODIMENTS

The following embodiments are exemplary. Although the specification may refer to “an”, “one”, or “some” embodiment(s) in several locations of the text, this does not necessarily mean that each reference is made to the same embodiment(s), or that a particular feature only applies to a single embodiment. Single features of different embodiments may also be combined to provide other embodiments.

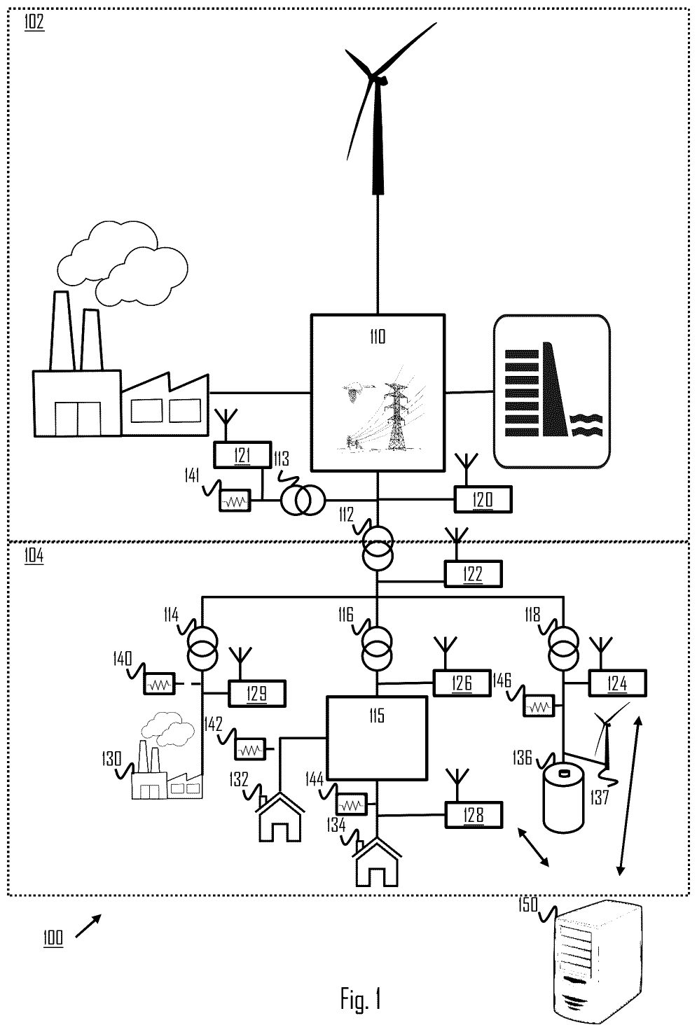

Supply of electricity from providers such as power stations, to consumers, such as domestic households, offices, industry, etc. typically takes place via an electricity distribution network or electric power grid. FIG. 1 shows an exemplary electric power grid 100, in which embodiments of the present invention may be implemented, comprising a transmission grid 102 and a distribution grid 104.

The transmission grid 102 is connected to power generators, which may be power plants such as nuclear plants, hydroelectric power plants, wind generators or gas-fired plants, for example, from which it transmits large quantities of electrical energy at very high voltages (typically of the order of hundreds of kilovolts, kV), over power lines such as overhead power lines 110, to the distribution grid 104.

The transmission grid 102 is linked to the distribution grid 104 via a transformer 112, which converts the electric supply to a lower voltage, typically of the order of 66 kV, for distribution in the distribution grid 104.

The distribution grid 104 is connected via substations 114, 116, 118 comprising further transformers for converting to still lower voltages to local networks which provide electric power to power consuming devices connected to the electric power grid. The local networks may include networks of domestic consumers, such as a city network 115 that supplies power to domestic appliances within private residences 132, 134 that draw a relatively small amount of power in the order of a few kW. The private residences may also use photovoltaic devices or other power generators to provide relatively small amounts of power for consumption either by appliances at the residence or for provision of power to the grid. The local networks may also include industrial premises such as a factory 130, in which larger appliances operating in the industrial premises draw larger amounts of power in the order of several kW to MWs. The local networks may also include networks of smaller power generators such as wind farms that provide power to the electric power grid. The local networks may further comprise energy storage devices 136 to store electric power locally. Such storage devices 136 may be used to compensate for a difference between supply and demand of electric power.

Although, for conciseness, only one transmission grid 102 and one distribution grid 104 are illustrated in FIG. 1, in practice a typical transmission grid 102 supplies power to multiple distribution grids 104 and one transmission grid 102 may also be interconnected to one or more other transmission grids 102.

Electric power flows in the electric power grid as alternating current (AC), which flows at a system frequency, which may also be referred to as a grid frequency (typically in the range of 50 or 60 Hz, depending on the country). The electric power grid operates at a synchronized frequency so that the frequency is substantially the same at each point of the grid. The electric power grid may include one or more direct current (DC) interconnects (not shown) that provide a DC connection between the electric power grid and other electric power grids. Typically, the DC interconnects connect to the high voltage transmission grid 102 of the electrical power grid. The DC interconnects provide a DC link between the various electric power grids, such that the electric power grid defines an area which operates at a given, synchronised, grid frequency that is not affected by changes in the grid frequency of other electric power grids. For example, the UK transmission grid is connected to the Synchronous Grid of Continental Europe via DC interconnects.

The electric power grid 100 also includes a measurement system in the form of measurement devices 120 to 129 at given measurement points of the grid arranged to measure the electric power grid. The measurement devices 120 to 129 may be configured to measure one or more electric parameters of the electric power grid at the given measurement points. At least some of the measurement devices 120 to 129 may be measurement points at the distribution grid 104, such as the measurement devices 122 to 129, but some of the measurement devices 120, 121 may be at measurement points at the transmission grid. The measurement device 120 is coupled directly to a high-voltage bus while the measurement device 121 is coupled to a lower-voltage-level bus of the transmission grid 102. A separate transformer 113 may be provided to transform the higher voltage level to the lower voltage level. As illustrated in FIG. 1, the measurement devices may be coupled to various measurement points at various voltage levels of the electric power grid. For example, the measurement device 120 coupled to the transmission grid 102 may be configured to perform measurements at the very high voltage level of the transmission grid, e.g. 132 kV. The measurement device 122 may be coupled to the distribution grid to perform measurement at a lower voltage level, e.g. 11 or 33 kV. The measurement devices 124 to 129 may be coupled to the distribution grid at a still lower voltage level or levels such as 220 V, 400 V, and/or 11 kV. The voltage level at the measurement device 121 may also be the still lower voltage level such as 220 V, 400 V, or 11 kV. The reader is reminded that the actual voltage levels are merely exemplary, and different electric power grids may employ different voltage levels.

Although, for the sake of simplicity, only a few measurement devices are illustrated in FIG. 1, it will be understood that, in practice, a higher number of such measurement devices may be coupled to the electric power grid, at various voltage levels and/or at various measurement points such as at different sub-stations or sub-networks of the electric power grid. It should also be appreciated that some embodiments may employ the measurement devices on only a subset of the voltage levels of the electric power grid or the distribution network 104.

In general, electric parameter(s) of interest may include at least one of the following: a voltage waveform, voltage quality, voltage transient, a current (instantaneous or continuous supply), a grid frequency, a phasor, a phase angle, reactive power, synchronous oscillations voltage and/or current magnitude, voltage and/or current phase. A time stamp may be provided in connection with each measurement. In some embodiments, the measurement devices are configured to process the measurement data into a higher-level measurement data. For example, the measured voltage and current may be used to compute a fault level at the location of the measurement device. The fault level at a location may be defined as a maximum current that would flow in case of a short circuit fault at that location. In some literature, the fault level is known as short circuit capacity or grid strength. The fault level may be measured from effects of voltage fluctuations in the electric power grid, e.g. by using a concept of Thevenin equivalents. Upon detecting a voltage fluctuation in the electric power grid, a source impedance at the measurement location may be computed by using the following Equation:

$${\vec{Z}}_{FL} = - \frac{Δ \vec{V}}{Δ \vec{I}} = - \frac{{\vec{V}}_{post} - {\vec{V}}_{pre}}{{\vec{I}}_{post} - {\vec{I}}_{pre}}$$

where Z_{FL} is the source impedance, \vec{V}ₚᵣₑ and \vec{I}ₚᵣₑ are voltage and current phasor measurements before a stimulus causing the voltage fluctuation, respectively, and \vec{V}ₚₒₛₜ and \vec{I}ₚₒₛₜ are voltage and current phasor measurements after the stimulus, respectively. The fault level SFL may then be computed by using the following Equation:

$${\vec{S}}_{FL actual} = \frac{{\vec{V}}_{actual}^{2}}{{\vec{Z}}_{FL}}$$

where Z_{FL} is the source impedance calculated during the event, \vec{V}_{actual} is the voltage measured at the observation time which could be before or after the event depending on which fault level is of most interest.

Below, some embodiments of the stimulus are described.

In order to carry out the measurements, the measurement devices 120 to 129 may each comprise a voltage detector arranged to sample the measured voltage and an analogue to digital converter arranged to convert the sampled voltage to a digital voltage signal. The measurement devices 120 to 129 may each also comprise a current detector arranged to sample the current, and the analogue to digital converter may be arranged to convert the sampled current to a digital current signal. The digital voltage signal and the digital current signal may then be forwarded to the processing system 150 for processing or be processed locally at the respective measurement device. The measurement devices 120 to 129 may each comprise one or both of the voltage detector and the current detector. When a sampling interval is sufficient, the grid frequency may be computed from the measured voltage and/or current.

In some embodiments, at least some of the measurement devices 120 to 129 comprise processing means, for example, in the form a processor, and the processor of the measurement device 120 to 129 may be arranged to determine an electric parameter relating to the measured voltage and/or current. This may be advantageous in that it may reduce the amount of information needing to be communicated by the measurement device 120 to 129 to the processing system, and also that it may reduce the burden placed on the processing system 150.

In an embodiment, the measurement system comprises means for causing a voltage modulation signal in the electric power grid. The voltage modulation signal may be generated by a suitable signal modulator, for example.

In an embodiment, the measurement system comprises means for detecting a fluctuation on the power grid. Such fluctuations are random events in the grid and may be caused by switching, load change, or transformer tapping, for example, i.e. forced, ambient or transient oscillations in the electric power grid. By examining the occurrence of these fluctuations on the grid it is possible to determine properties of the grid including voltage sensitivity and harmonics. In combination or separately using a voltage modulated signal injected onto the grid, it is also possible to measure and or estimate the same properties and also short circuit level (fault level) using measurement devices to see the effect that generated signal has on voltage at various points across the electric power grid.

FIG. 1 illustrates multiple devices 140 to 146 that are coupled to the electric power grid. The devices 140 to 146 may comprise signal modulators that, when connected to the electric power grid, cause a change in the voltage of the electric power grid. In an embodiment, the signal modulators may cause a sinusoidal signal in the voltage of the electric power grid. Sinusoidal signals have the same general shape, but they do not have the same characteristics. There are three characteristics that distinguish one sinusoid from another: amplitude, frequency, and phase.

The measurement devices may be configured to report the measurement data to a processing system 150. The processing system 150 may be configured to analyse the measurement data and, in some embodiments, perform some control of the electric power grid on the basis of the analysis. Detailed embodiments are described below. The processing system may comprise a processing circuitry in the form of one or more computers. The processing system may include a local network server, a remote server, a cloud-based server, or any other means for carrying out the analysis of the measurement data. The processing system may form a virtual network for carrying out the analysis. In general, virtual networking may involve a process of combining hardware and software network resources and network functionality into a single, software-based administrative entity, a virtual network. Network virtualization may involve platform virtualization, often combined with resource virtualization. Network virtualization may be categorized as external virtual networking which combines many networks, or parts of networks, into a server computer or a host computer. A virtual network may provide flexible distribution of operations between various processing units for performing the analysis.

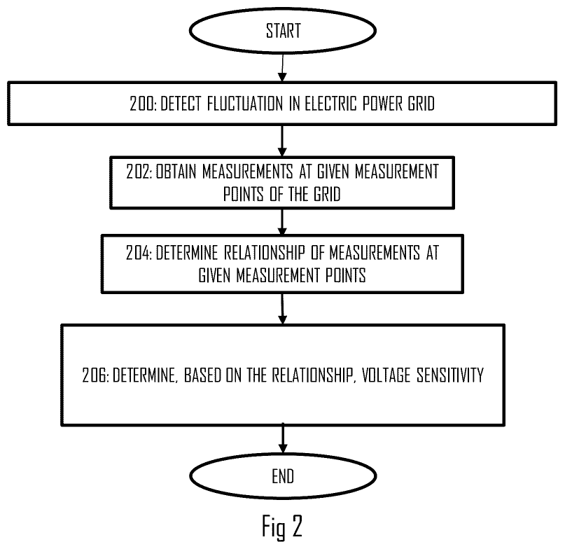

FIG. 2 is a flow diagram illustrating an embodiment of monitoring of an electric power grid and determining relative voltage sensitivity or system strength of the electric power grid.

In step 200, a fluctuation is detected in the electric power grid. This may be performed by the measurement devices, for example. In another embodiment, a voltage modulation signal is directly caused. This may be performed, for example, by the devices 140 to 146 which may comprise signal modulators. The voltage modulation signal may be a known controlled or autonomously generated signal onto the electric grid that can be read by the measurement devices and from those measurements, the same system parameters, voltage stiffness and short circuit level for example can be calculated.

In step 202, while the fluctuation is effective, measurements of one or more electrical parameters in the electric power grid at a given number of grid measurement points are obtained. This may be performed, for example, by the measurement devices 120 to 129. The measurement devices may measure the effect of the voltage modulation signal at the given grid measurement points.

In an embodiment, measurements of one or more electrical parameters comprises measuring voltage waveform amplitudes derivatives, transients and shapes.

In step 204, a relationship of the measured parameters at the given number of grid measurement points is determined, at least in part based on the one or more electrical parameters. If voltage modulation signal is used the properties of the voltage modulation signal is taken into account. This may be performed, for example, by the processing system 150.

In step 206, relative voltage sensitivity those measurement points have relative to the detected fluctuation is determined based on the relationship. This may be performed, for example, by the processing system 150. In an embodiment, also system strength parameters or voltage stiffness, harmonics and fault level may be determined.

In an embodiment, one of the objectives is to determine how voltage waveform amplitudes derivatives, transients and shapes (which would include aspects such as voltage RMS, harmonics, and other distortions of power quality) correlate between different measurement points. It is also possible to measure current in the measurement points to find short circuits fault level.

It is possible to solve various problems related to power systems by using statistical analysis of the measurement results. in this situation. Correlation coefficients or other analytical techniques to represent the relationship of the measurement points can be used to evaluate the relationship between different variables from a statistical perspective.

When relationships between two nodal voltages are strong, nodal voltage of one measurement point has a greater impact on nodal voltage of the second measurement point, and deviation between distinguished measurement points is more evident. This analysis can result in propagation analysis of voltage sensitivity in the distribution grid, which can show valuable information about the grid.

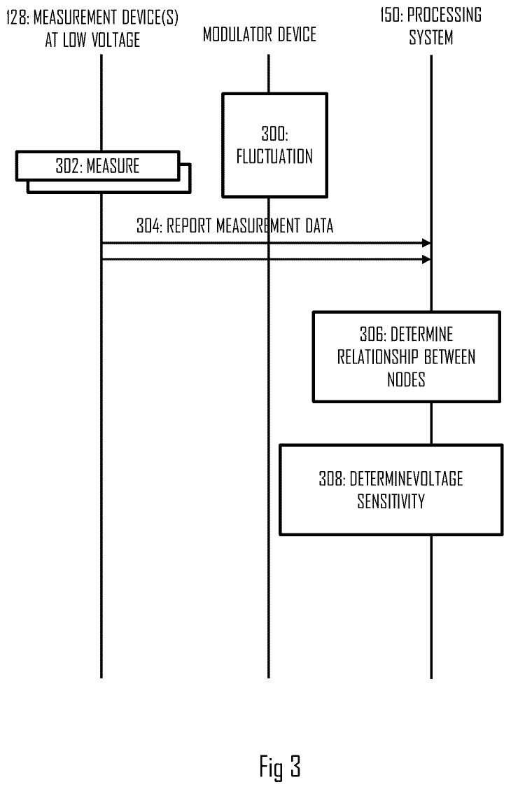

FIG. 3 illustrates a signalling diagram of an embodiment. The devices 140 to 146 which may comprise signal modulators cause a voltage modulation signal 300 in the electric power grid. The modulation signal and/or other fluctuation signal used for analysis may have an effective duration illustrated in FIG. 3 by the box 300. While the modulation and/or other fluctuation is in effect, the measurement data may be acquired 302 by the measurement device(s) under the effective area of the modulation signal. Step 302 may comprise measuring voltage waveform amplitudes derivatives, transients and shapes at the given measurement points, for example, the voltage and current at the given measurement points of the electric power grid. Upon performing the measurements, the measurement device(s) may report the measurement data to the processing system 150 in step 304. Such a measurement report may be provided in the form of a Comtrade or other similar data file formats, for example.

From a further perspective, the measurements performed in step 302 may be called active measurements if the intentionally generated voltage modulation signal is used to carry out the measurement(s). As illustrated in FIG. 3, multiple measurements may be performed under the influence of the voltage modulation signal. Multiple voltage modulation signals may also be generated as well, at different locations on the electric power grid. The triggering of the voltage modulation signals may be synchronous such that the voltage modulation signals or other reference signal may occur substantially simultaneously at the different locations. The synchronization may be realized by using a common time reference such a Global Positioning System clock. The synchronous voltage modulation or other reference signals implicitly cause synchronous measurements at the different measurement points (or a subset thereof) in step 302. This enables a snapshot of the electric state of the low-voltage level of the entirety of or a large area of the electric power grid. Accordingly, the calculations of correlations may be made more accurate thanks to the synchronous measurements.

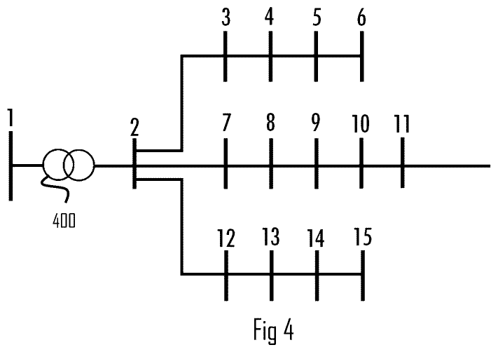

FIG. 4 illustrates a simple example of a part of an electric grid. FIG. 4 illustrates an example of determining, in this case, correlational relationships between measurement points and determination of relative voltage sensitivity or system strength parameters. It may be noted that the calculation can be done with several methodologies.

The example shows the upstream grid 1, a transformer 400, and buses 2 to 15. Let us assume that an event, such as a voltage modulation signal, occurs at bus 6. The voltage changes at bus 6 will be propagated to other buses, according to the impedance between buses as shown below, based on the Superposition Theorem:

$$Δ {V}_{6} = ( {Z}_{t h} + {Z}_{12} + {Z}_{23} + {Z}_{34} + {Z}_{45} + {Z}_{56} ) * Δ I$$

$$Δ {V}_{5} = ( {Z}_{t h} + {Z}_{12} + {Z}_{23} + {Z}_{34} + {Z}_{45} ) * Δ I$$

$$Δ {V}_{4} = ( {Z}_{t h} + {Z}_{12} + {Z}_{23} + {Z}_{34} ) * Δ I$$

$$Δ {V}_{3} = ( {Z}_{t h} + {Z}_{12} + {Z}_{23} ) * Δ I$$

$$Δ {V}_{2} = ( {Z}_{t h} + {Z}_{12} ) * Δ I$$

$$Δ {V}_{7} = Δ {V}_{8} = Δ {V}_{9} = Δ {V}_{10} = Δ {V}_{11} = Δ {V}_{12} = Δ {V}_{13} = Δ {V}_{13} = Δ {V}_{14} = Δ {V}_{15} = Δ {V}_{2}$$

where ΔI is the current change in bus 6, ΔVᵢ is the voltage change in bus i, Zᵢⱼ is the impedance between bus i and bus j, and Zₜₕ is the equivalent impedance of the upstream grid. The sensitivity of these voltage changes to each other can be presented in a matrix, called the voltage sensitivity matrix:

$$Voltage sensitivity matrix = [ \begin{matrix}\frac{Δ {V}_{1}}{Δ {V}_{1}} & … & \frac{Δ {V}_{1}}{Δ {V}_{n}} \\ ⋮ & ⋱ & ⋮ \\ \frac{Δ {V}_{n}}{Δ {V}_{1}} & … & \frac{Δ {V}_{n}}{Δ {V}_{n}}\end{matrix} ]$$

Each element of the voltage sensitivity matrix, ΔVi/ΔVj, from each event, can reveal some data from impedance between lines. For example, in the above-mentioned event in the bus 6, the main elements of voltage sensitivity matrix will be

$$Δ {V}_{5} / Δ {V}_{6} = ( {Z}_{t h} + {Z}_{12} + {Z}_{23} + {Z}_{34} + {Z}_{45} ) / ( {Z}_{t h} + {Z}_{12} + {Z}_{23} + {Z}_{34} + {Z}_{45} + {Z}_{56} )$$

$$Δ {V}_{4} / Δ {V}_{6} = ( {Z}_{t h} + {Z}_{12} + {Z}_{23} + {Z}_{34} ) / ( {Z}_{t h} + {Z}_{12} + {Z}_{23} + {Z}_{34} + {Z}_{45} + {Z}_{56} )$$

$$Δ {V}_{3} / Δ {V}_{6} = ( {Z}_{t h} + {Z}_{12} + {Z}_{23} ) / ( {Z}_{t h} + {Z}_{12} + {Z}_{23} + {Z}_{34} + {Z}_{45} + {Z}_{56} )$$

$$Δ {V}_{2} / Δ {V}_{6} = ( {Z}_{t h} + {Z}_{12} ) / ( {Z}_{t h} + {Z}_{12} + {Z}_{23} + {Z}_{34} + {Z}_{45} + {Z}_{56} )$$

$$Δ {V}_{7} / Δ {V}_{6} = Δ {V}_{8} / Δ {V}_{6} = Δ {V}_{9} / Δ {V}_{6} = ( {Z}_{t h} + {Z}_{12} ) / ( {Z}_{t h} + {Z}_{12} + {Z}_{23} + {Z}_{34} + {Z}_{45} + {Z}_{56} )$$

$$Δ {V}_{10} / Δ {V}_{6} = Δ {V}_{11} / Δ {V}_{6} = Δ {V}_{12} / Δ {V}_{6} = Δ {V}_{13} / Δ {V}_{6} = ( {Z}_{t h} + Z 12 ) / ( {Z}_{t h} + {Z}_{12} + {Z}_{23} + {Z}_{34} + {Z}_{45} + {Z}_{56} )$$

$$Δ {V}_{13} / Δ {V}_{6} = Δ {V}_{14} / Δ {V}_{6} = Δ {V}_{15} / Δ {V}_{6} = ( {Z}_{t h} + Z 12 ) / ( {Z}_{t h} h + {Z}_{12} + {Z}_{23} + {Z}_{34} + {Z}_{45} + {Z}_{56} )$$

The elements of the voltage sensitivity matrix show the rate of impedance between different measurement points and the equivalent of the upstream grid. For example, if the system is stronger, Zₜₕ will be smaller, and sensitivity of measurement point 7-15 to measurement point 6 will be a very small value.

In an embodiment, it is possible to analyse the sensitivity matrix after each event in the grid and utilise an artificial intelligence-based approach in the determination of the relative voltage sensitivity or system strength of different buses.

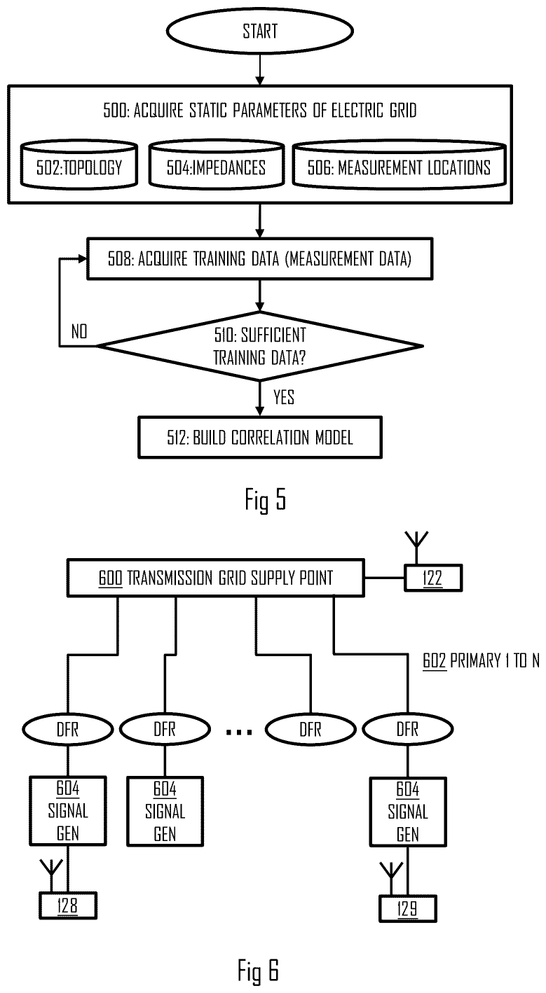

Referring to FIG. 5, the processing system 150 may first acquire static parameters of the electric power grid (block 500). Such static parameters may include a topology 502 of the electric power grid, defined in terms of interconnections of elements of the electric power grid. FIG. 1 illustrates one topology of the electric power grid. The topology 502 may thus represent the structure of the electric power grid or a subset thereof, depending on the intended coverage of the correlation model. The static parameters may include impedances (504) at various locations of the electric power grid. The impedance values describe electric inter-relations between the various parts of the electric power grid and, thus, may be utilized in the correlation model or other analytical model to assess relationships between measurement points. The static parameters may include the measurement locations at given measurement points 506, i.e. the measurement points to which the measurement devices 120 to 129 are coupled. The static parameters may further include a network status and a power generation profile of the power supply system. The network status may describe a state of power lines, transformers, load(s), and/or generator(s), for example. Additional static parameters may be provided, e.g. the locations of the signal generators 140 to 146, weather data, temperature data, solar irradiation data, pricing tariffs, market mechanisms and responses to those mechanisms, usage/consumption and generation models of the electric power grid, including for example traffic flows within the electric power grid. The static parameters may form one set of training data for forming the correlation model. The static parameters may comprise or be comprised in information on electric characteristics of the electric power grid.

In block 508, the processing system gathers another set of training data for forming the correlation or relationship model. This set of training data may comprise the measurement data measured from the electric power grid. The measurement data may comprise the above-described measurement data received by the processing system in steps 304, for example. As described above, the measurement data may include any one or more of a voltage, current, grid frequency, or above-described higher level measurement data.

The processing system may monitor 510 when a sufficient amount of training data has been gathered. A parameter for block 510 may be a number of different measurement devices that have reported the measurement data. If a sufficient number of measurement devices have reported the measurement data, it may be determined the sufficient amount of measurement data is available. If the sufficient amount of measurement data is not available, further measurement data may be gathered.

Upon gathering the sufficient amount of training data, the process may proceed to block 512 where a correlation model of the correlations between given measurement points is built by the processing system. Block 512 may comprise executing a machine learning algorithm using the above-described sets of training data as inputs for the machine learning. The machine learning algorithm may employ a neural network such as a deep neural network or a recursive neural network to form the correlation model. In general, the machine learning algorithm may search for patterns in the measurement data with the basic knowledge of the static parameters acquired in block 500. By analyzing the measurement data and the static parameters, the above-described correlation model within a voltage level and even across multiple voltage levels can be built.

When the correlation model has been built (block 510 completed), the correlation model may be used to determine, based on the correlations, relative voltage sensitivity or system strength parameters of the electric power grid.

In an embodiment, the model may also map an electric parameter measured at given measurement point to a corresponding electric parameter of another measurement point from which the measurement data is not currently available or is out-of-date. The correlation model may also enable forecasting or predicting future behavior of the electric parameter at the measurement point or location from which the measurement data is not currently available or is out-of-date, by using measurement data acquired from another measurement point or location of the electric power grid. This may enable prediction of future development of the fault level, for example. An embodiment thus uses block 510 to compute the correlation model that represents the electric parameter during the measurements used as the basis for the correlation model.

As set out in this example, the correlation model (which could also be alternative analytical approaches) enables maintenance of the overall view of the electric power grid whenever measurement data from at least one location is received. The correlation model may map a single piece of measurement data received from a single measurement location to the overall view of the electric power grid. As a consequence, there is no need to provide the measurement devices at all locations where the electric parameter is needed. Furthermore, it is not necessary to receive the up-to-date measurement data from all the measurement locations as frequently. When the correlation model is accurate, the measurement data only from a single measurement location or a subset of the measurement locations is sufficient for the processing system to evaluate the electric parameter over the coverage area of the correlation model. As described above, the coverage area spans over multiple measurement locations and over multiple devices at the different locations of the electric power grid.

FIG. 6 illustrates a simplified structure of the electric power grid to which the measurement devices may be coupled. As described above, one measurement device 122 may be coupled to a higher voltage level, e.g. to a transmission grid supply point 600. Multiple primary buses 1 to N 602 may be coupled to the transmission grid supply point, and a digital fault recorder (DFR) or a similar measurement device may be coupled to each primary bus or a subset of the primary buses 1 to N. The DFR is an example of the above-described measurement devices 120 to 129. In an embodiment, the DFR is configured to carry out the measurements based on the voltage modulation signal and/or another fluctuation detected in the electric power grid. The DFRs may all be provided in the same unit of the electric power grid, e.g. a sub-station, but each DFR may be connected to a different primary bus, thus being connected to different points in the electric power grid. In other embodiments, the DFRs are provided in multiple units, e.g. different sub-stations, thus providing a broader overview of the fault level in the electric power grid or a sub-network of the electric power grid. Signal modulators 602 or similar devices used for generating the intentional disturbances may be coupled to the primary buses or a subset thereof, as illustrated in FIG. 6, and a measurement device 128, 129 may be coupled to a location of each signal generator 602 or a subset of the signal generator 602. As illustrated in FIG. 6, the measurement data may be provided on various voltage levels, three in this embodiment. The measurement device 122 carries out the measurement on the highest voltage level, the DFRs carry out the measurements on a lower voltage level, and the measurement devices carry out the measurements on the lowest voltage level.

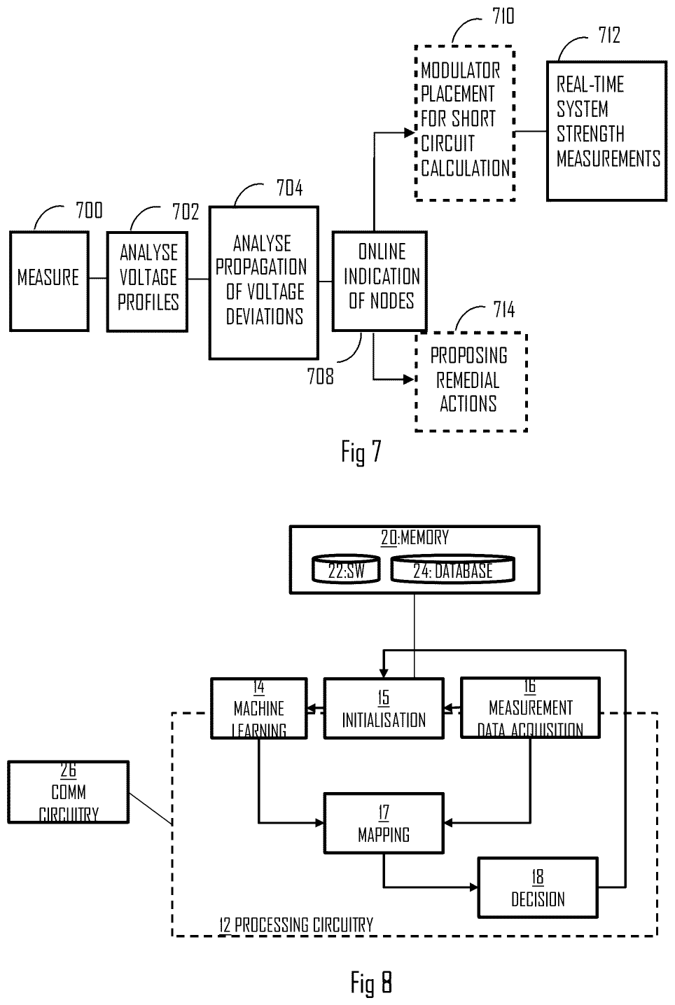

FIG. 7 illustrates an example of the operation of a measuring system of an embodiment.

The system comprises measuring voltage modulation 700 at given measurement points of the electric grid. Time stamped measurements are obtained. The measurements may be realised with the measurement devices 120 to 129. The measured voltage profiles at the given measurement points may be analysed 702. The voltage deviations would be traced, for example

The relationship or correlation between voltage deviations of different buses may be determined 704. This is a complex challenge that requires data analysis to identify the pattern of voltage deviations from different measurement points and origins. By finding the strongest relationships or correlations within the voltage changes of the grid under study, it is possible to identify the measurement points that are more sensitive to voltage deviations. If there is between grid measurement points a large mutual correlation, they are likely to have also have a large mutual voltage sensitivity, and thus a small system strength between the measurement points. Accordingly, if there is small mutual correlation, they are likely to have also have small mutual voltage sensitivity, and thus a large system strength between the measurement points.

Indication of found results regarding the relative voltage sensitivity or system strength (for example) may be provided 708. For example, the results may be shown by the processing system to relevant electric grid system personnel. The obtained data may be utilised in various ways. When the strongest correlations within the voltage changes of the grid under study are found, it may be possible to identify the measurement points that are most sensitive to voltage deviations. For example, suggestions 710 of locations or measurement points where signal generators and current measurements are placed may be provided, to obtain efficient data on the relative voltage sensitivity or system strength of the grid in the context of short circuit faults. Further, real time relative voltage sensitivity or system strength measurements 712 may be obtained.

FIG. 8 illustrates an embodiment of an apparatus configured to carry out at least some of the above-described functions. The apparatus may comprise an electronic device comprising at least one processor or processing circuitry 12 and at least one memory 20. The apparatus may comprise a single computer or a computer system such as the cloud computing system described above. The apparatus may further comprise a communication circuitry 26 connected to the processing circuitry. The communication circuitry 26 may comprise hardware and software suitable for supporting one or more computer network protocols such as an Internet protocol (IP), Ethernet protocol, etc.

The memory 20 may store a computer program (software) 22 comprising computer program code defining the functions of the processing circuitry 12. The computer program code may, when read and executed by the processing circuitry 12, cause the processing circuitry to execute the process of FIG. 2, blocks 300 to 308 of FIG. 3, or any one of the embodiments as a computer-implemented process. The memory may further store a database 24 storing the correlation model and the voltage sensitivity matrix, the acquired measurement data, and the static parameters of the electric power grid.

The processing circuitry 12 may comprise a measurement data acquisition circuitry 16 configured to acquire the measurement data from the measurement devices coupled to the electric power grid and to store the measurement data in the database. Upon acquiring a sufficient amount of measurement data, the measurement data acquisition circuitry 16 may control an initialisation circuitry 15 to initialize a procedure for generating or calibrating a correlation model and the voltage sensitivity matrix. The initialisation may comprise retrieval of the static parameters of the electric power grid and the measurement data and input of the information to a machine learning circuitry 14. The static parameters may comprise internal parameters of the electric power grid such as impedances in the electric power grid, power supply/consumption profile, topology, etc. That static parameters may comprise parameters external to the electric power grid such as weather profile, pricing tariffs, solar irradiation patterns, etc. The machine learning circuitry 14 may then execute block 710 and form or update the correlation model. Upon completing the correlation model, the machine learning circuitry 14 stores the correlation model and voltage sensitivity matrix in the database. It may also notify a mapping circuitry 17 of the availability of the (updated) correlation model. Upon computing new electric parameters, the new electric parameters may be output to a decision circuitry 18 configured to determine relative voltage sensitivity or system strength related parameters. The decision circuitry 18 may also determine whether or not a recalibration of the correlation model is needed. If the calibration is needed, the decision circuitry may configure the initialisation circuitry 15 to initialize the calibration in a manner similar to that described above.

As used in this application, the term ‘circuitry’ refers to all of the following: (a) hardware-only circuit implementations, such as implementations in only analog and/or digital circuitry, and (b) combinations of circuits and software (and/or firmware), such as (as applicable): (i) a combination of processor(s) or (ii) portions of processor(s)/software including digital signal processor(s), software, and memory(ies) that work together to cause an apparatus to perform various functions, and (c) circuits, such as a microprocessor(s) or a portion of a microprocessor(s), that require software or firmware for operation, even if the software or firmware is not physically present. This definition of ‘circuitry’ applies to all uses of this term in this application. As a further example, as used in this application, the term ‘circuitry’ would also cover an implementation of merely a processor (or multiple processors) or a portion of a processor and its (or their) accompanying software and/or firmware. The term ‘circuitry’ would also cover, for example and if applicable to the particular element, a baseband integrated circuit or applications processor integrated circuit for a mobile phone or a similar integrated circuit in a server, a cellular network device, or another network device.

In an embodiment, at least some of the processes described in connection with the above figures may be carried out by an apparatus comprising corresponding means for carrying out at least some of the described processes. Some example means for carrying out the processes may include at least one of the following: detector, processor (including dual-core and multiple-core processors), digital signal processor, controller, receiver, transmitter, encoder, decoder, memory, RAM, ROM, software, firmware, display, user interface, display circuitry, user interface circuitry, user interface software, display software, circuit, antenna, antenna circuitry, and circuitry. In an embodiment, the at least one processor, the memory, and the computer program code form processing means or comprises one or more computer program code portions for carrying out one or more operations according to any one of the embodiments described in connection with the above figures.

According to yet another embodiment, the apparatus carrying out the embodiments comprises a circuitry including at least one processor and at least one memory including computer program code. When activated, the circuitry causes the apparatus to perform at least some of the functionalities according to any one of the embodiments described in connection with above.

The techniques and methods described herein may be implemented by various means. For example, these techniques may be implemented in hardware (one or more devices), firmware (one or more devices), software (one or more modules), or combinations thereof. For a hardware implementation, the apparatus(es) of embodiments may be implemented within one or more application-specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, other electronic units designed to perform the functions described herein, or a combination thereof. For firmware or software, the implementation can be carried out through modules of at least one chip set (e.g., procedures, functions, and so on) that perform the functions described herein. The software codes may be stored in a memory unit and executed by processors. The memory unit may be implemented within the processor or externally to the processor. In the latter case, it can be communicatively coupled to the processor via various means, as is known in the art. Additionally, the components of the systems described herein may be rearranged and/or complemented by additional components in order to facilitate the achievements of the various aspects, etc., described with regard thereto, and they are not limited to the precise configurations set forth in the given figures, as will be appreciated by one skilled in the art.

Embodiments as described may also be carried out in the form of a computer process defined by a computer program or portions thereof. Embodiments of the methods described in connection with the above figures may be carried out by executing at least one portion of a computer program comprising corresponding instructions. The computer program may be in source code form, object code form, or in some intermediate form, and it may be stored in some sort of carrier, which may be any entity or device capable of carrying the program. For example, the computer program may be stored on a computer program distribution medium readable by a computer or a processor. The computer program medium may be, for example but not limited to, a record medium, computer memory, read-only memory, electrical carrier signal, telecommunications signal, and software distribution package, for example. The computer program medium may be a non-transitory medium, for example. Coding of software for carrying out the embodiments as shown and described is well within the scope of a person of ordinary skill in the art. In an embodiment, a computer-readable medium comprises said computer program.

Even though the invention has been described above with reference to an example according to the accompanying drawings, it is clear that the invention is not restricted thereto but can be modified in several ways within the scope of the appended claims. Therefore, all words and expressions should be interpreted broadly, and they are intended to illustrate, not to restrict, the embodiment. It will be obvious to a person skilled in the art that, as technology advances, the inventive concept can be implemented in various ways. Further, it is clear to a person skilled in the art that the described embodiments may, but are not required to, be combined with other embodiments in various ways.

### CLAUSES

Clause 1. A method for monitoring an electric power grid, the method comprising:
detecting a fluctuation on the power grid;
obtaining, while the fluctuation is effective, measurements of one or more electrical parameters in the electric power grid at a given number of grid measurement points;
determining, at least in part based on the one or more electrical parameters and the properties of the fluctuation, the relationship of the measured parameters at the given number of grid measurement points;
determining, based on the relationship, relative voltage sensitivity those measurement points have relative to the detected fluctuation.

Clause 2. The method of clause 1, where the fluctuation is at least one of an intentionally caused voltage modulation or a fluctuation on the power grid caused by forced, ambient or transient oscillations in the electric power grid.

Clause 3. The method of clause 1 or 2, wherein the relationship is correlation.

Clause 4. The method of clause 1, 2 or 3, wherein measurements of one or more electrical parameters comprise measuring voltage waveform amplitudes, derivatives, transients and shapes.

Clause 5. The method of any preceding clause 1 to 4, further comprising forming, by using machine learning, the relationship between different two or more measurement points of the electric power grid by using, as training data, a first set of measurement data obtained at the first measurement point and a second set of measurement data obtained at the second measurement point.

Clause 6. The method of clause 5, wherein the first measurement point is at a first voltage level and the second measurement point is at a second voltage level different from the first voltage level.

Clause 7. The method of clause 5, wherein the first measurement point and the second measurement point are both located on the same voltage level of the electric power grid.

Clause 8. A system (120-129, 150) for monitoring an electric power grid (100), the system comprising means for performing:
detecting a fluctuation on the power grid;
obtaining, while the fluctuation is effective, measurements of one or more electrical parameters in the electric power grid at a given number of grid measurement points;
determining, at least in part based on the one or more electrical parameters and the properties of the fluctuation, the relationship of the measured parameters at the given number of grid measurement points;
determining, based on the relationship, relative voltage sensitivity those measurement points have relative to the detected fluctuation.

Clause 9. The system of clause 8, where the fluctuation is at least one of an intentionally caused voltage modulation or a fluctuation on the power grid caused by forced, ambient or transient oscillations in the electric power grid.

Clause 10. The system of claim 8 or 9, wherein the relationship is correlation.

Clause 11. The system of clause 8, 9, or 10, wherein measurements of one or more electrical parameters comprises measuring voltage waveform amplitudes, derivatives, transients and shapes.

Clause 12. The system of clause 8, the system comprising means for forming, by using machine learning, the relationship between different two or more measurement points of the electric power grid by using, as training data, a first set of measurement data obtained at the first measurement point and a second set of measurement data obtained at the second measurement point.

Clause 13. A computer program product readable by a computer and comprising computer program instructions that, when executed by the computer cause execution of a computer process comprising:
detecting a fluctuation on the power grid;
obtaining, while the fluctuation is effective, measurements of one or more electrical parameters in the electric power grid at a given number of grid measurement points;
determining, at least in part based on the one or more electrical parameters and the properties of the voltage modulation signal, relationship of the measured parameters at the given number of grid measurement points;
determining, based on the relationship, relative voltage sensitivity those measurement points have relative to the detected fluctuation.

1. A method for monitoring an electric power grid, the method comprising:
detecting a fluctuation on the power grid;
obtaining, while the fluctuation is effective, measurements of one or more electrical parameters in the electric power grid at a plurality of grid measurement points; and
determining, based on the measurements of the one or more electrical parameters, and a characteristic of the fluctuation, voltage sensitivity at each measurement point relative to the detected fluctuation.

2. The method of claim 1, where the fluctuation is at least one of an intentionally caused voltage modulation or a fluctuation on the power grid caused by forced, ambient or transient oscillations in the electric power grid.

3. The method of claim 1, wherein the measurements of the one or more electrical parameters comprise voltage waveform amplitudes, derivatives, transients and shapes.

4. The method of claim 1, further comprising forming, by using machine learning, the relationship between a first measurement point and a second measurement point in the electric power grid by using, as training data, a first set of measurement data obtained at the first measurement point and a second set of measurement data obtained at the second measurement point.

5. The method of claim 4, wherein the first measurement point is at a first voltage level and the second measurement point is at a second voltage level different from the first voltage level.

6. The method of claim 4, wherein the first measurement point and the second measurement point are both located on the same voltage level of the electric power grid.

7. A system for monitoring an electric power grid, the system comprising means for performing:
detecting a fluctuation on the power grid;
obtaining, while the fluctuation is effective, measurements of one or more electrical parameters in the electric power grid at a plurality of grid measurement points; and
determining, based on the measurements of the one or more electrical parameters, and a characteristic of the fluctuation, voltage sensitivity at each measurement point relative to the detected fluctuation.

8. The system of claim 7, where the fluctuation is at least one of an intentionally caused voltage modulation or a fluctuation on the power grid caused by forced, ambient or transient oscillations in the electric power grid.

9. The system of claim 7, wherein the measurements of the one or more electrical parameters comprise voltage waveform amplitudes, derivatives, transients and shapes.

10. The system of claim 7, the system comprising means for forming, by using machine learning, the relationship between a first measurement point and a second measurement point in the electric power grid by using, as training data, a first set of measurement data obtained at the first measurement point and a second set of measurement data obtained at the second measurement point.

11. A computer program product readable by a computer and comprising computer program instructions that, when executed by the computer cause execution of a computer process comprising:
detecting a fluctuation on the power grid;
obtaining, while the fluctuation is effective, measurements of one or more electrical parameters in the electric power grid at a plurality of grid measurement points; and
determining, based on the measurements of the one or more electrical parameters, and a characteristic of the fluctuation, voltage sensitivity at each measurement point relative to the detected fluctuation.
